(19) United States
(12) Patent Application Publication
(10) Pub. No.: US 2011/0233660 A1
(43) Pub. Date: Sep. 29, 2011

(54) SEMICONDUCTOR DEVICE AND MANUFACTURE THEREOF

(75) Inventor: Tomonari OOTA, Osaka (JP)

(73) Assignee: PANASONIC CORPORATION, OSAKA (JP)

(21) Appl. No.: 13/042,801

(22) Filed: Mar. 8, 2011

Related U.S. Application Data
(63) Continuation-in-part of application No. PCT/JP2010/002083, filed on Mar. 24, 2010.

(51) Int. Cl. H01L 29/78; H01L 21/336

(52) U.S. Cl. 257/330; 438/270; 257/E29.262; 257/E21.41

(57) ABSTRACT

A downwardly convex bowed shape is given to an upper edge Tw2 of each of trenches, whereby contact resistance is reduced without involvement of an increase in pitch at which trenches are to be formed. Specifically, each of the trenches includes a bowed surface Tw2 whose opening edge is outwardly convex when viewed in cross section and a source contact region that is formed between a source electrode filled along the bowed surface Tw2 and a source region formed along the bowed surface Tw2.

### BACKGROUND

1. Field of the Invention

The present invention relates to a semiconductor device and manufacture thereof, particularly to a reduction in on-resistance of a semiconductor device, such as an insulation gate transistor having a trench structure.

2. Description of the Related Art

With a reduction in power consumption, greater sophistication, and a speedup of electronic devices, including a portable phone, a growing demand recently exists for a reduction in power consumption and a speedup of a semiconductor device accommodated in the electronic devices. To meet the demand, transistors used in load switches, DC-DC converters, and the like, of electronic devices, transistors exhibiting smaller on-resistance are generally required to exhibit smaller on-resistance. One proposed method for reducing on-resistance is to miniaturize individual devices to thereby increase density of transistors to be placed per unit area. Specifically, a density of transistors in a vertical MOSFET having gate electrodes formed in trenches can be increased by means of: placing the trenches, which make up transistors, in the form of a stripe pattern; miniaturizing a width of each of the trenches; and reducing a pitch between adjacent trenches.

The T_MOSFET is a MOSFET that utilizes sidewalls of each of trenches as channels by means of embedding gate electrodes into the respective trenches by way of a gate insulation film.

FIG. 8 (FIG. 1 of Patent Document 1) shows a typical n-channel T_MOS structure. An epitaxial layer 1810 is formed over a silicon substrate that is an n⁺-type semiconductor substrate 1800 doped with n-type (a first conductivity type) impurities by means of an epitaxial growth technique. The epitaxial layer 1810 includes an n-type drain region 1811, a p-type body region 1812 formed on the drain region 1811, an n⁺-type source region 1813 formed on the body region 1812, and a p⁺-type body contact region 1814 that is formed so as to be adjacent to the source region 1813 and that is higher than the body region 1812 in terms of a concentration of impurities. The epitaxial layer 1810 includes a trench that penetrates through the source region 1813 and the body region 1812 and that reaches an upper portion of the drain region 1811, and a vertical gate electrode 1820 is embedded in the trench. The top surface of the vertical gate electrode 1820 is formed so as to situate at a position that is lower than a surface of the epitaxial layer 1810 that includes the source region 1813. Further, an interior space of the trench located above the vertical gate electrode 1820 is filled with an insulation film 1830. Further, an insulating substance 1840 that is to serve as a gate insulation film is present in a space between the drain region 1811 and the vertical gate electrode 1820 and a space between surfaces of the body regions 1812 that are to act as vertical wall surfaces of the trench and the vertical gate electrode 1820. A common electrode 1850 commonly connected to the source region 1813 and the body contact region 1814 is laid on a surface of the epitaxial layer 1810.

In order to meet a demand for a further reduction in on-resistance and further miniaturization of a chip; namely, an increase in current density, various techniques intended for a further miniaturization of trench pitch have recently been put forward.

FIG. 8 shows an example trench pitch miniaturization technique in a T_MOS of Patent Document 2. In order to reduce a trench pitch, a width of each of trenches and an interval between the trenches are reduced. If the pitch width of the trench is reduced while the structure shown in FIG. 8 is maintained, an area of the source region 1813 and an area of the body contact region 1814 will become smaller. For this reason, contact resistance existing between body contact electrode metal serving as the common electrode 1850 and the source region 1813, the body contact region 1814 becomes greater; hence, it is difficult to reduce on-resistance as intended. For these reasons, in Patent Document 2, an upper edge of an insulating substance 2140 filled in each of the trenches is given a round shape as shown in FIG. 8. The length of a channel (i.e., the length of a gate electrode 2120) per trench is made greater, whereby the number of trenches is reduced, and an interval between trenches is increased. An area between the body contact and a source contact is effectively increased, whereby an increase in contact resistance, which would otherwise be incidental to miniaturization, can be prevented. It has been said that the trench pitch can be reduced from an order of micrometers to an order of sub-microns; specifically, one micrometer or less, by use of the technique.
Patent Document 1: JP-A-2006-196876
Patent Document 2: JP-A-2005-32792

However, a geometry of a trench greatly affects an element characteristic with additional miniaturization of an element. In particular, contact resistance of a source contact located in a vicinity of opening of the trench and resistance of a source region become a cause of an increase in on-resistance.

### SUMMARY

The present invention has been conceived in light of the circumstance and aims at reducing source resistance, which in turn reduces on-resistance.

To this end, the inventors of the present patent application conducted various tests and finally found that contact resistance can be reduced without involvement of an increase in pitch at which trenches are formed, by means of giving a downwardly convex shape to an upper edge of each of trenches.

A semiconductor device of the present invention comprises: a drain region that is formed from a semiconductor region of first conductivity type; a body region that is formed from a semiconductor region of second conductivity type and on the drain region; a source region that is formed in the body region and that is formed from the semiconductor region of first conductivity type; a body contact region that is formed from a high concentration semiconductor region of second conductivity type and that is located in an area within the body region which differs from the source region; trenches that each are formed so as to extend from the source region to the drain region while penetrating through the body region; a gate electrode that is formed within each of the trenches; a source electrode that is formed so as to contact the source region and the body contact region; and a drain electrode formed in the drain region, wherein the trench includes a bowed surface whose opening edge is outwardly convex when viewed in cross section and a source contact region formed between the source electrode filled along the bowed surface and the source region formed along the bowed surface.

The present invention is also the semiconductor device, wherein, when viewed in cross section, the trench has vertical surfaces that vertically extend and bowed surfaces formed on respective upper edges of the vertical surfaces; and wherein each of the bowed surfaces is formed so as to extend from an edge of an insulation film covering the gate electrode to an upper edge of a source region.

The present invention is also the semiconductor device, wherein the semiconductor device is a SiMOSFET formed on the silicon substrate.

The present invention is also a method for manufacturing a semiconductor device comprising the steps of: forming a semiconductor layer of first conductivity type on a semiconductor substrate of first conductivity type by means of epitaxial growth; introducing impurities of second conductivity type into the semiconductor layer of first conductivity type while a semiconductor region of first conductivity type that is to become a drain region is left, thereby forming a body region of second conductivity type; forming trenches at a desired pitch so as to reach the drain region; forming a source region from the semiconductor region of first conductivity type that is formed in the body region formed on the drain region and from a semiconductor region of second conductivity type; forming a body contact region formed from a high concentration semiconductor region of second conductivity type and in an area within the body region which differs from the source region; forming a gate electrode within each of the trenches; forming a source electrode so as to contact the source region and the body contact region by covering the gate electrode with an insulation film; and forming a drain electrode so as to contact the drain region, wherein the step of forming the trenches includes a step of forming an oxide film on a surface of the semiconductor substrate in which there is formed the body region of second conductivity type, thereby forming a mask pattern from the oxide film; a first step of forming a bowed surface by means of isotropic etching while the mask pattern is taken as a mask; and a second step of forming vertical surfaces by means of anisotropic etching.

The present invention is also the method for manufacturing the semiconductor device, wherein the first step includes an etching step using fluorinated gas and O₂, the second step includes an etching step using fluorinated gas and Ar.

The present invention is also the method for manufacturing the semiconductor device, wherein the step of forming the mask pattern from the oxide film includes a first preprocessing step that is comprised by an anisotropic etching and a second preprocessing step that is composed by an isotropic etching.

The present invention is also the method for manufacturing the semiconductor device, wherein the first preprocessing step includes an etching step using CF₄ and Ar, the second preprocessing step includes an etching step using CF₄ and O₂.

The present invention is also the method for manufacturing the semiconductor device, wherein the second preprocessing step and the first step are continuous steps that are performed in same condition.

As mentioned above, according to the present invention, a source region makes up a downwardly convex surface. Therefore, a contact area between the source region and a source electrode (a source contact area) is increased as much as about 30%. With a reduction in the area of the source region, an area that is to become a source electrode is increased correspondingly. Hence, an attempt can be made to significantly reduce on-resistance.

### BRIEF DESCRIPTION OF THE DRAWINGS

FIG. 1 is a cross sectional view showing a T_MOSFET of a first embodiment of the invention;

FIG. 2 is a top view of FIG. 1;

FIG. 3 is an oblique perspective view showing the T_MOSFET of the first embodiment of the present invention.

FIG. 4 is an explanatory view of geometry of a trench in the T_MOSFET of the first embodiment of the present invention.

FIGS. 5 (a) to (d) are cross sectional views showing processes for manufacturing the T_MOSFET of the first embodiment of the present invention.

FIGS. 6 (a) to (c) are cross sectional views showing processes for manufacturing the T_MOSFET of the first embodiment of the present invention.

FIGS. 7 (a) to (d) are cross sectional views showing processes for manufacturing the T_MOSFET of the second embodiment of the present invention.

FIG. 8 is a cross sectional view showing a related-art T_MOSFET.

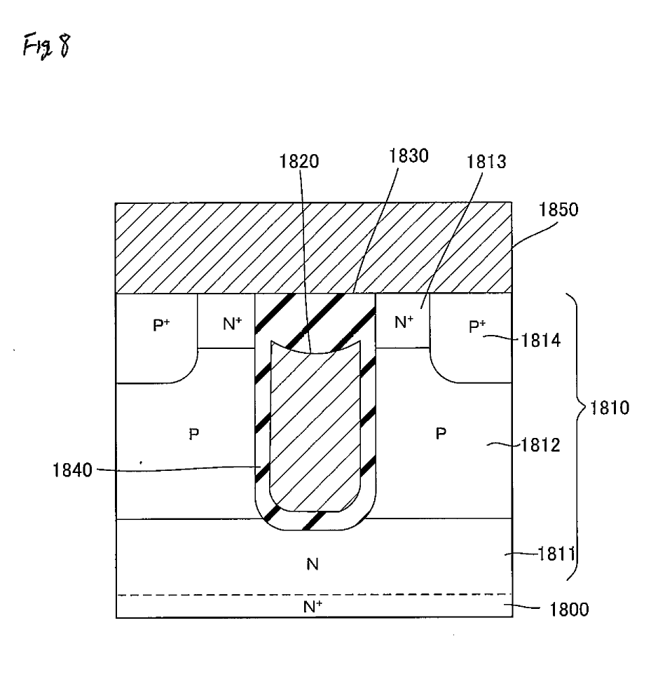

FIG. 9 is an explanatory view showing the related-art T_MOSFET.

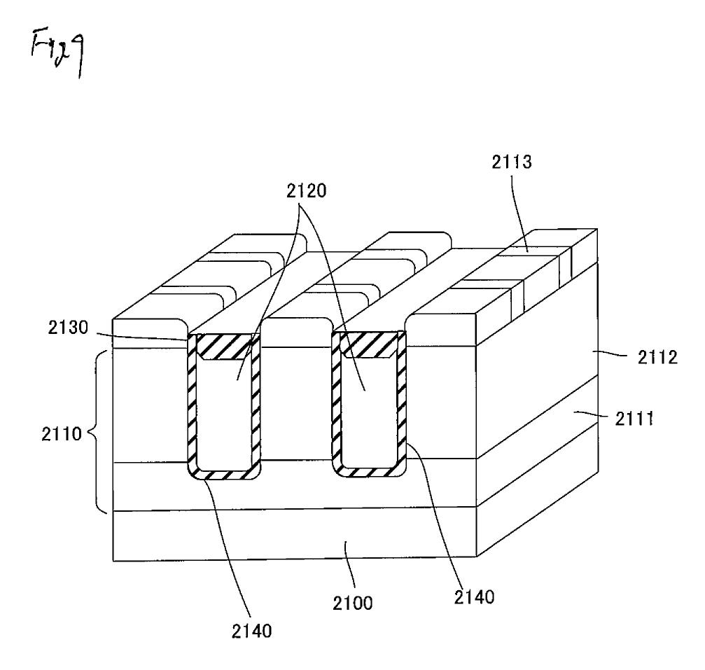

### DETAILED DESCRIPTION

By reference to the drawings, embodiments of the present invention are hereunder described in detail.

### First Embodiment

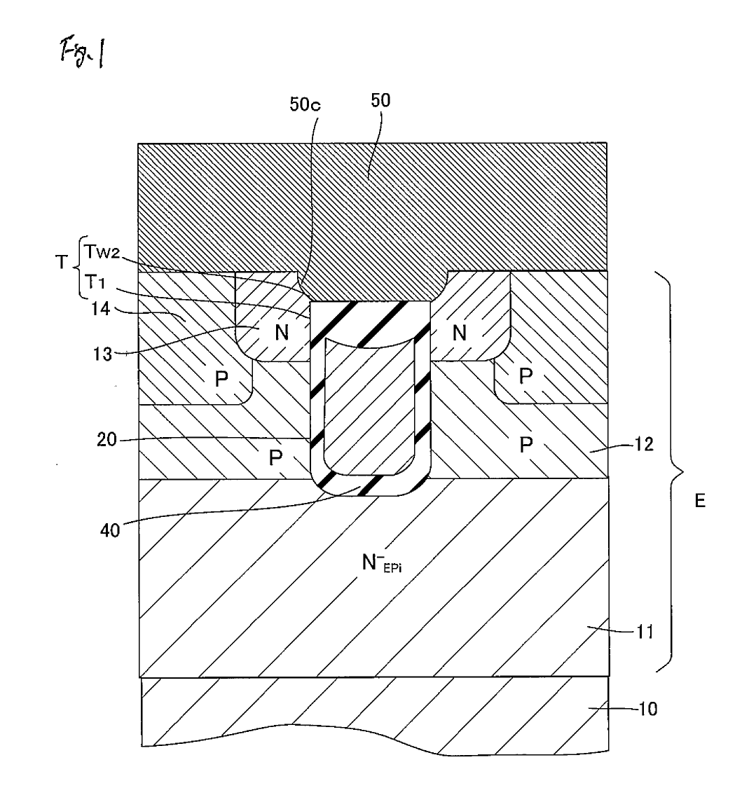

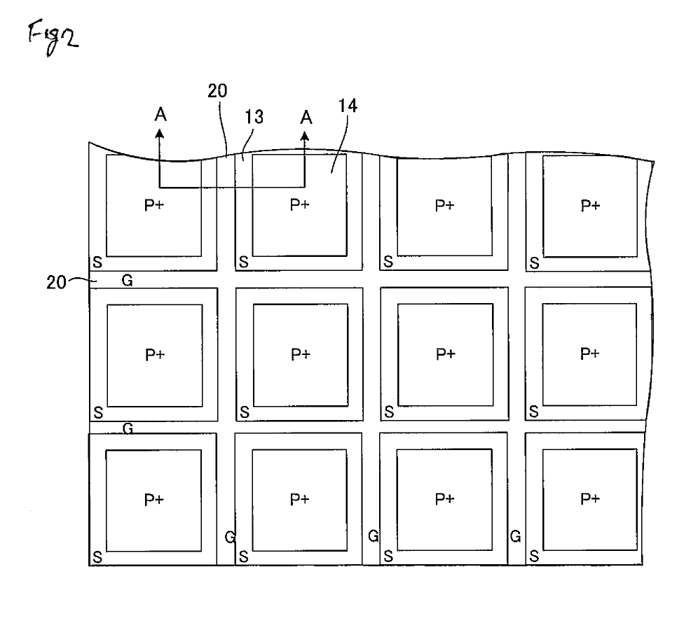

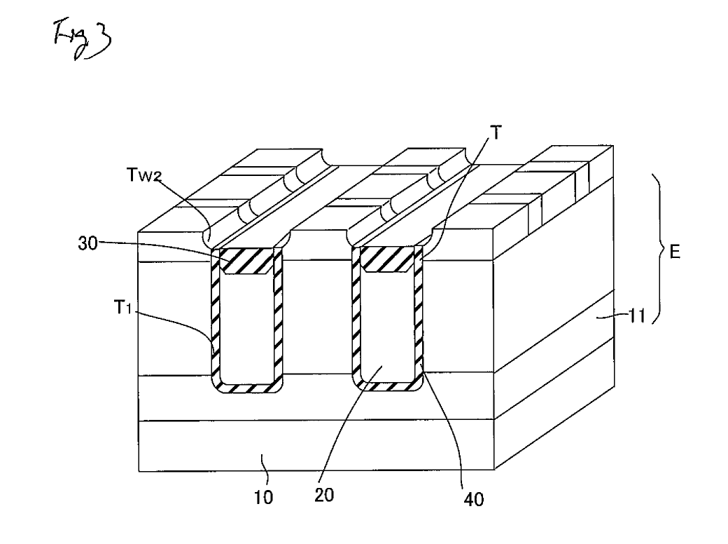

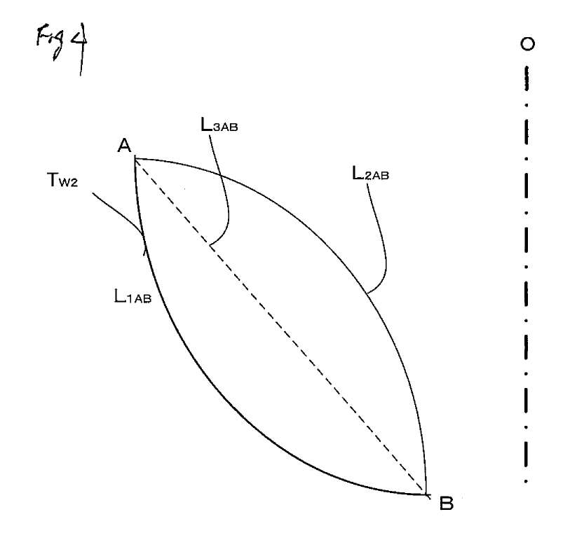

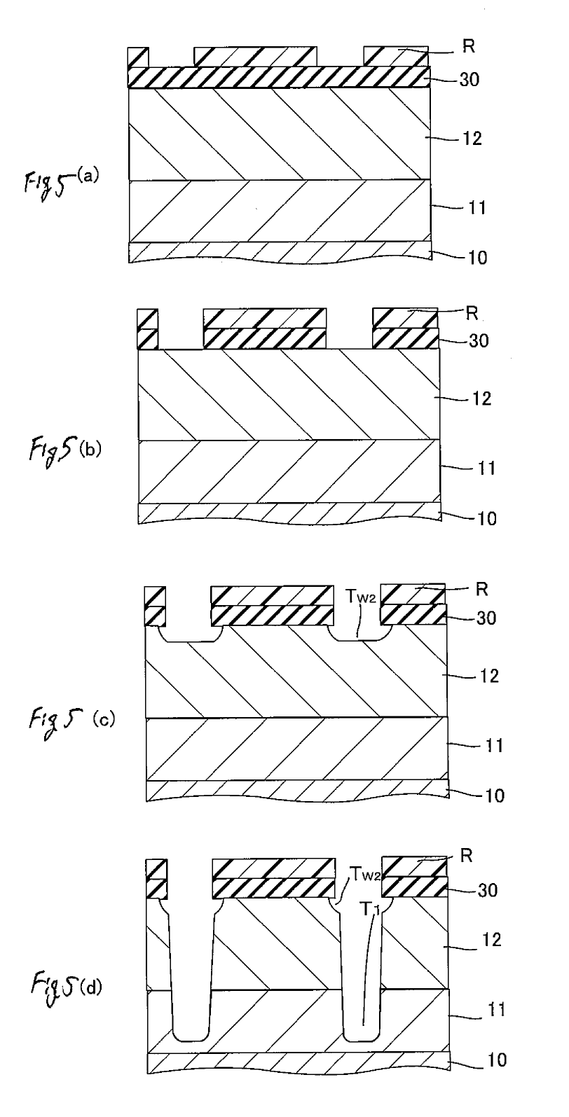

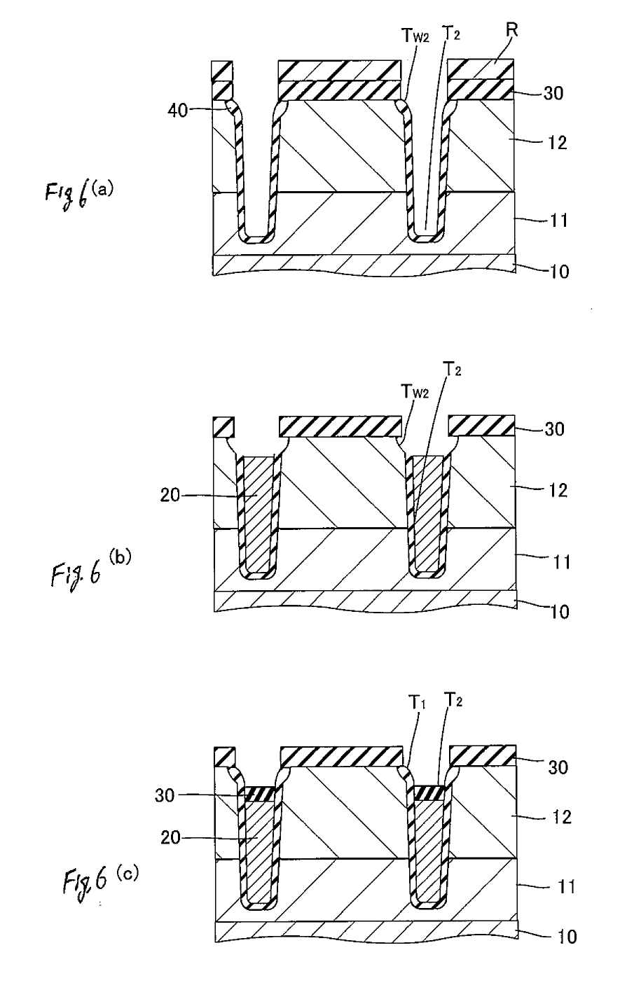

FIGS. 1 through 3 are views showing a T_MOSFET having a trench of a first embodiment of the present invention. FIG. 4 is an explanatory view of geometry of the trench. FIGS. 5(a) to (d) and FIGS. 6(a) to (c) are process cross sectional views showing a general outline of a method for manufacturing a semiconductor device of the present invention. FIG. 1 is a cross sectional view; FIG. 2 is a top view; and FIG. 3 is an oblique perspective view. FIG. 1 is a view showing a cross section taken along line A-A shown in FIG. 2.

The T_MOSFET of the first embodiment has the following features. Specifically, each of trenches T includes a bowed surface Tw2 whose opening edge is outwardly convex when viewed in cross section. The T_MOSFET has a source electrode 50 formed in the bowed surface Tw2, and a source contact region 50c provided along the bowed surface Tw2.

Specifically, as can be seen from the cross section of FIG. 1, the T_MOSFET has a drain region 11 that is formed from an n-type epitaxial layer formed over a surface of an n⁺-type silicon substrate 10; a body region 12 that is formed from a p-type well region formed over the drain region 11; a source region 13 that is formed from an n-type region made in the body region 12; a body contact region 14 that is formed from a p⁺-type region and in an area of the body region 12 differing from a location of the source region 13; the trenches T that each are formed so as to extend from the source region 13 to the drain region 11 while penetrating through the body region 12; a gate electrode 20 that is formed from a polysilicon layer in the trench T by way of a silicon oxide film 40 serving as a gate insulation film; the source electrode 50 formed so as to contact the source region 13 and the body contact region 14; and a drain electrode formed in the n⁺-type silicon substrate 10 serving as a drain region.

On occasion of manufacture of the T_MOSFET, a mask pattern of a silicon oxide film 30 is formed in a process of forming the trench T. The silicon substrate is etched in two steps by way of the mask pattern. A cross section of the trench has a vertical surface T1 extending in the vertical direction and the bowed surface Tw2 formed at an upper edge of the vertical surface. The bowed surface Tw2 is formed so as to extend from a peripheral edge of an insulation film covering a top of the gate electrode 20 to an upper edge of the source region. As can be seen from the explanatory view of FIG. 4, the trench T has a bowed surface that downwardly protrudes when viewed in cross section (that is downwardly convex). Specifically, an area of a region that takes as one side a downwardly-curved line L_{1AB} with reference to a center axis O and that has a predetermined width acts as a contact area S_{1AB} (see FIG. 3). In the meantime, the trench described in connection with Patent Document 2 has a surface whose upper edge is rounded; namely, a bowed surface that upwardly projects when viewed in cross section (is convex upwardly). Specifically, an area defined when a curve line L_{2AB} that is upwardly convex with reference to the center axis O is taken as one line acts as a contact area S_{2AB}.

Since there stands L_{1AB}>L_{2AB}, We consequently have

S_{1AB}>S_{2AB .}

As mentioned, in the case of the trench having a downwardly convex surface, it is obvious that the contact area S_{1AB} becomes significantly greater than the contact area S_{2AB} achieved in the case of a bowed surface that upwardly projects when viewed in cross section.

When the trench is simply given a tapered surface; namely, when a straight line L_{3AB} is taken as one side of the trench with reference to the center axis O, a contact area S_{3AB} having a predetermined width achieved at this time is smaller than the contact area achieved when the trench has the downwardly convex surface. However, the contact area S_{3AB} becomes greater than the contact area S_{2AB} having a predetermined width achieved when the trench has the upwardly convex curve line L_{2AB} as one side as in the related art.

L_{1AB}>L_{3AB}>L_{2AB}, therefore

we have

S_{1AB}>S_{3AB}>S_{2AB .}

For these reasons, the contact area existing between the source region and the source electrode is understood to have significantly increased as compared with the contact area of the T_MOSFET having an upwardly rounded, convex shape. Further, it is also obvious that the source electrode has increased by an amount corresponding to a reduction in the size of the source region.

As mentioned above, on-resistance of the T_MOSFET of the present embodiment is understood to have become smaller than that of the relate-art T_MOSFET. In reality, the contact area of the T_MOSFET of the present embodiment is increased by about 30% when compared with the contact area of the related-art T_MOSFET. Moreover, the size of the source electrode is increased by an amount corresponding to a reduction in the size of the source region, so that on-resistance can be significantly reduced.

The T_MOSFET of the present embodiment is hereunder described by reference to the drawings.

The T_MOSFET is basically analogous to the n-channel T_MOSFET described in connection with the first embodiment. As shown in FIGS. 1 through 3, an epitaxial layer E is formed, through epitaxial growth, over the n⁺-type silicon substrate 10 serving as a semiconductor substrate doped with n-type (first conductivity type) impurities. A bottom of the epitaxial layer E is taken as the n-type drain region 11. An impurity diffused region is formed within the epitaxial layer E. The p-type body region 12 is formed over the drain region 11, and the n-type source region 13 is formed over the surface of the body region 12. The p⁺-type body contact region 14 is doped with impurities of the same conductivity type so as to become higher in concentration than the body region 12 and also becomes adjacent to the source region 13. The trench T is formed in the epitaxial layer E so as to penetrate through the source region 13 and the body region 12 and extends up to an upper portion of the drain region 11. The vertical gate electrode 20 made of doped polysilicon is embedded in the trench T. The top surface of the vertical gate electrode 20 is formed so as to situate at a level that is, by a predetermined depth, lower than a surface of the epitaxial layer E where the source region 13 exists. A space located above the vertical gate electrode 20 within the trench T is filled with the silicon oxide film 30 serving as an insulation film. Further, the silicon oxide film 40 serving as a gate insulation film exists between the drain region 11 and the vertical gate electrode 20 and between surfaces of the body regions 12 serving as vertical wall surfaces of the trench and the vertical gate electrode 20. Further, the source electrode 50 serving as a common electrode to be connected commonly to the source region 13 and the body contact region 14 is formed over the epitaxial layer E.

A method for manufacturing the T_MOSFET of the present invention is now described.

First, the epitaxial layer E is formed, through epitaxial growth, over the n⁺-type silicon substrate 10 serving as a semiconductor substrate. A silicon oxide layer having a thickness of about 700 nm is formed over the surface of the epitaxial layer E by means of thermal oxidation. A mask used for creating a p-type well region is formed, and the silicon oxide layer is patterned by use of the mask. The silicon oxide layer is doped with p-type impurities by means of ion implantation, thereby forming the p-type well region that is to be the body region 12.

Subsequently, a resist pattern R used for forming a trench is formed as shown in FIG. 5(a).

The silicon oxide film 30 is then patterned by using the resist pattern R as a mask as shown in FIG. 5(b).

A gas mixture consisting of a fluorine-based gas and oxygen is used as an etching gas as shown in FIG. 5(c) while the silicon oxide film 30 is taken as a mask. The pattern is then subjected to dry etching at a temperature of 50 to 100° C. for 0.5 minutes to two minutes, thereby creating a trench having the bowed surface Tw2.

Subsequently, a gas mixture consisting of a fluorine-based gas, Ar, and oxygen is used as an etching gas as shown in FIG. 5(d), and the pattern is subjected to anisotropic etching at a temperature of 50 to 100° C. for two to four minutes, thereby creating the trench T having a cross section made up of the vertical surface T1.

The element region and the electrodes are now created. Brief descriptions are here provided by reference to FIGS. 6(a) to (c).

As shown in FIG. 6(a), an interior wall of the trench T formed within the epitaxial layer E formed over the N⁺-type silicon substrate 10 is thermally oxidized, to thus create the silicon oxide film 40. As shown in FIG. 6(b), a polysilicon film that is to become the gate electrode 20 is deposited in and on the trench T. Impurities are then introduced into the polysilicon film in such a way that a desired concentration is accomplished.

As mentioned above, after formation of the embedded layer, the silicon oxide film 30 is formed as an interlayer insulation film by means of the CVD technique. The silicon oxide film is subjected to back etching, to thus reveal the bowed surface Tw2 of the trench.

Subsequently, n-type impurities are sequentially implanted, to thus create the source region 13, as shown in FIG. 6(c). Further, p-type impurities are implanted, to thus create the body contact region 14.

After the silicon oxide film 30 serving as an interlayer insulation film has been formed by means of the CVD technique, an aluminum layer is finally formed as the source electrode 50, and the thus-formed source electrode is patterned.

Processing pertaining to a series of procedures shown in FIGS. 5(a) to 5(d) and FIGS. 6(a) to 6(c) is performed, so that the T_MOSFET of the present invention can be manufactured.

### Second Embodiment

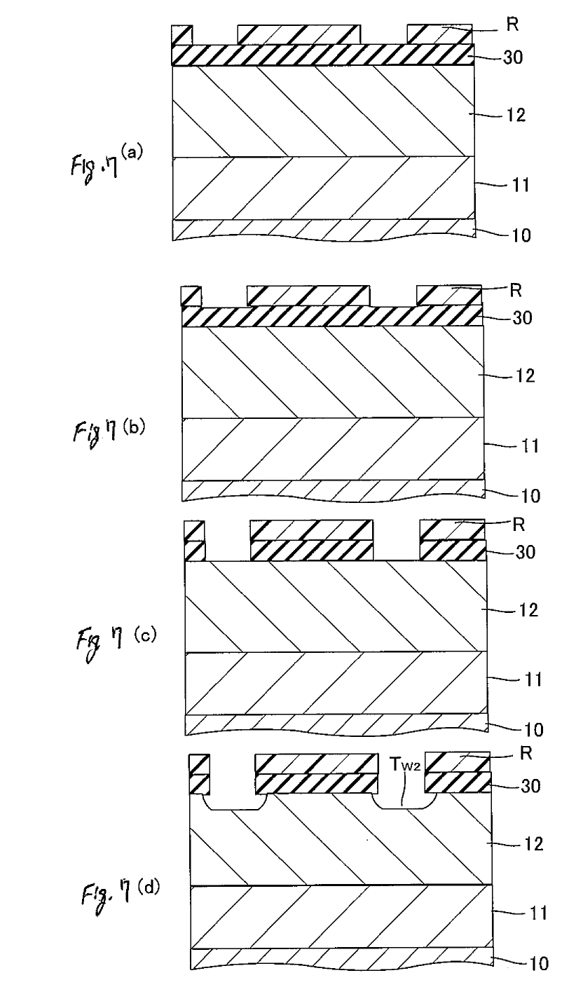

FIGS. 7(a) to (c) are process cross sectional views showing a general outline of a method for manufacturing a semiconductor device of the second embodiment of the present invention. FIGS. 7(a) to (c) are a modification of the step of forming the trench in FIGS. 5(a) to (c).

The T_MOSFET of the second embodiment has the following features as same as the first embodiment. Specifically, each of trenches T includes a bowed surface Tw2 whose opening edge is outwardly convex when viewed in cross section. A source contact region 50c is formed between the source electrode 50 filled along the bowed surface Tw2 and the source region 13 formed along the bowed surface Tw2.

Specifically, on occasion of forming the trench seen from the cross section of FIG. 1, etching is performed in two steps by changing the kinds of the gas in the step of forming the silicon oxide film 30. As a result, T_MOSFET is formed so that the profile of the trench T is made so as to include the bowed surface Tw2 whose opening edge is outwardly convex when viewed in cross section.

Since the other parts are same as those of the first embodiment, explanation for the other parts is omitted. Same number is applied to same part.

On occasion of manufacture of the T_MOSFET, a mask pattern of a silicon oxide film 30 is formed in a process of forming the trench T. The silicon substrate is etched in two steps by the mask pattern. A cross section of the trench has a vertical surface T1 extending in the vertical direction and the bowed surface Tw2 formed at an upper edge of the vertical surface. The bowed surface Tw2 is formed so as to extend from a peripheral edge of an insulation film covering a top of the gate electrode 20 to an upper edge of the source region.

In the embodiment, the step of patterning the silicon oxide film 30 is performed by two steps of anisotropic etching and isotropic etching.

That is, as shown in FIG. 7(a), the resist pattern is firstly formed as same as the first embodiment. And hereafter, as shown in FIG. 7(b), after the anisotropic etching is firstly performed by the mixture gas of CF₄ and Ar, a part of the silicon oxide film is etched so as to be the pattern faithfully corresponding to the resist pattern by the anisotropic etching. Next, as shown in FIG. 7(c), the isotropic etching by the mixture gas of CF₄ and O₂ is performed so that the opening of the silicon oxide film 30 spreads. Further, by using the silicon oxide film as a mask and using the fluorinated gas and O₂ as the etching gas, a dry etching of the temperature 50 to 100° C. and 0.5 to 2 minutes is performed. As shown in FIG. 7(d), the trench including the bowed surface Tw2 is formed. Hereafter, as shown in FIG. 5(d), by using CF4 gas and Ar, by the anisotropic etching of the temperature 50 to 100° C. and 2 to 4 minutes, the trench T having a vertical surface T1 is formed. As same as the explanatory view of FIG. 4, the trench T has a bowed surface that downwardly protrudes when viewed in cross section (that is downwardly convex). Specifically, an area of a region that takes as one side a downwardly-curved line L_{1AB} with reference to a center axis O and that has a predetermined width acts as a contact area S_{1AB} (see FIG. 3). In the meantime, the trench described in connection with Patent Document 2 has a surface whose upper edge is rounded; namely, a bowed surface that upwardly projects when viewed in cross section (is convex upwardly). Specifically, an area defined when a curve line L_{2AB} that is upwardly convex with reference to the center axis O is taken as one line acts as a contact area S_{2AB}.

As mentioned, in the case of the trench having a downwardly convex surface, the contact area S_{1AB} becomes significantly greater than the contact area S_{2AB} achieved in the case of a bowed surface that upwardly projects when viewed in cross section.

As mentioned above, on-resistance of the T_MOSFET of the present embodiment is understood to have become smaller than that of the relate-art T_MOSFET. In reality, the contact area of the T_MOSFET of the present embodiment is increased by about 30% when compared with the contact area of the related-art T_MOSFET. Moreover, the size of the source electrode is increased by an amount corresponding to a reduction in the size of the source region, so that on-resistance can be significantly reduced.

In the second embodiment, before etching in the two steps in the first embodiment, the pattern of the silicon oxide film faithfully corresponding to the resist pattern is formed by the anisotropic etching. Hereinafter, etching in two steps including the anisotropic etching and the isotropic etching is performed.

Each of condition is needed to be appropriately selected based on the pattern density. However, before etching in the two steps including the anisotropic etching and the isotropic etching, an anisotropic etching is added in the step of patterning the silicon oxide film. According to this, it is possible to obtain the trench having more pattern accuracy.

According to above, before the etching step using the fluorinated gas and Oₛ as the first step, the first preprocessing step that is the etching step using CF₄ and Ar is added for high accuracy of the mask pattern. Then, the second preprocessing step that is isotropic etching and the etching in two steps are performed for obtaining high accuracy of the outwardly convex when viewed in cross section. Herein, the etching step using CF₄ and O₂ is used as the second preprocessing step that is by the isotropic etching. According to this, it is possible to continue anisotropic etching of the silicon that is by using unchanged gas.

Also, after the first preprocessing step that is by the anisotropic etching and the second preprocessing step that is by the isotropic etching are performed as the step for forming the mask pattern from the oxide film, etching in the two steps can be performed as same as the first embodiment.

Although the silicon T_MOSFET using silicon has been described in the embodiment, the present invention is also effective for manufacturing a Schottky gate FET which does not include a gate insulation film and which includes a gate electrode formed directly in a trench and an IGBT employing the foregoing configuration in which a P-type substrate is taken as a substrate.

Although the silicon T_MOSFET using silicon has been described in the embodiment, the present invention is also applicable to T_MOSFET using SiC, GaN.

The method for manufacturing a semiconductor device of the present invention is effective for a trench gate MOS transistor. In addition to the trench MOS transistor, the present invention can also apply to a semiconductor device in which a minute, uniform trench pattern, such as a trench gate, is formed and in which the trench pattern formed area occupies the majority of a total area of a semiconductor device; for instance, an insulated trench gate bipolar transistor (a trench IGBT) and a semiconductor device having such a bipolar transistor.

What is claimed is:

1. A semiconductor device, comprising:
a drain region formed from a semiconductor region of first conductivity type;
a body region formed from a semiconductor region of second conductivity type and formed on the drain region;
a source region formed in the body region and formed from the semiconductor region of first conductivity type;
a body contact region formed from a high concentration semiconductor region of second conductivity type and located in an area within the body region which differs from the source region;
a trench formed so as to extend from the source region to the drain region while penetrating through the body region;
a gate electrode formed within the trench;
a source electrode formed so as to contact the source region and the body contact region; and
a drain electrode formed in the drain region;
wherein the trench includes a bowed surface whose opening edge is outwardly convex when viewed in cross section and a source contact region formed between the source electrode filled along the bowed surface and the source region formed along the bowed surface.

2. The semiconductor device according to claim 1, wherein, when viewed in cross section, the trench has vertical surfaces that vertically extend and bowed surfaces formed on respective upper edges of the vertical surfaces;
and each of the bowed surfaces is formed so as to extend from an edge of an insulation film covering the gate electrode to an upper edge of the source region.

3. The semiconductor device according to claim 1, wherein the semiconductor device is a SiMOSFET formed on a silicon substrate.

4. A method for manufacturing a semiconductor device comprising the steps of:
forming a semiconductor layer of first conductivity type on a semiconductor substrate of first conductivity type by means of epitaxial growth;
introducing impurities of second conductivity type into the semiconductor layer of first conductivity type while a semiconductor region of first conductivity type that is to become a drain region is left, so as to form a body region of second conductivity type;
forming a trench at a desired pitch so as to reach the drain region;
forming a source region from the semiconductor region of first conductivity type that is formed in the body region formed on the drain region and from a semiconductor region of second conductivity type;
forming a body contact region formed from a high concentration semiconductor region of second conductivity type and in an area within the body region which differs from the source region;
forming a gate electrode within the trench;
forming a source electrode so as to contact the source region and the body contact region by covering the gate electrode with an insulation film; and
forming a drain electrode so as to contact the drain region,
wherein the step of forming the trench includes
a step of forming an oxide film on a surface of the semiconductor substrate in which there is formed the body region of second conductivity type, thereby forming a mask pattern from the oxide film;
a first step of forming a bowed surface by means of isotropic etching while the mask pattern is taken as a mask; and
a second step of forming vertical surfaces by means of anisotropic etching.

5. The method for manufacturing the semiconductor device according to claim 4, wherein the first step includes an etching step using fluorinated gas and O₂, the second step includes an etching step using fluorinated gas and Ar.

6. The method for manufacturing the semiconductor device according to claim 4, wherein the step of forming the mask pattern from the oxide film includes a first preprocessing step by the anisotropic etching and a second preprocessing step by the isotropic etching.

7. The method for manufacturing the semiconductor device according to claim 6, wherein the first preprocessing step includes an etching step using CF₄ and Ar, the second preprocessing step includes an etching step using CF₄ and O₂.

8. The method for manufacturing the semiconductor device according to claim 7, wherein the second preprocessing step and the first step are continuous steps that are performed in same condition.
